(19) United States
(12) Patent Application Publication
(10) Pub. No.: US 2001/0019283 A1
(43) Pub. Date: Sep. 6, 2001

(54) High-speed dynamic latch

(76) Inventors: Gea-ok Cho, Suwon-city (KR); Min-kyu Song, Seoul (KR); Jung-eun Lee, Seoul (KR)

Correspondence Address: SUGHRUE, MION, ZINN, MACPEAK & SEAS, PLLC, 2100 Pennsylvania Avenue, N.W., Washington, DC, 20037-3202, US

(21) Appl. No.: 09/731,812

(22) Filed: Dec. 8, 2000

(30) Foreign Application Priority Data
Dec. 8, 1999 (KR) 99-55834

(51) Int. Cl. H03K 3/037

(52) U.S. Cl. 327/200; 327/215

(57) ABSTRACT

A dynamic latch that can be used in a high-speed analog-to-digital converter is provided. The dynamic latch includes a discharging unit which discharges a first output node in parallel in response to one of a pair of differential input signals and a second output node, and discharges the second output node in parallel in response to the other of the pair of differential input signals and the first output node, and a current source which sinks current from the discharging unit in response to a clock signal. The dynamic latch is capable of removing kick-back voltage which may occur in the existing latch and compensating for a drawback caused by a low-speed charge/discharge, which allows for improvement in operation speed.

### BACKGROUND OF THE INVENTION

1. Field of the Invention

The present invention relates to a high-speed dynamic latch, and more particularly, to a dynamic latch for a high-speed analog-to-digital (A/D) converter. The present application is based on Korean Patent Application No. 99-55834, which is incorporated herein by reference.

2. Description of the Related Art

Generally, a latch is used for latching an address, data or internal clock signals for a given period, or maintaining a specific mode. When it comes to an A/D converter for a high definition television (HDTV) and a partial response maximum likelihood (PRML) method, a high-speed latch is required.

FIG. 1 shows a conventional dynamic latch circuit. Referring to FIG. 1, the latch circuit is operated in a track mode in which a clock signal CLK is in a logic low state and in a latch mode in which a clock signal CLK is in a logic high state. Specifically, when the latch circuit is in a track mode, PMOS transistors P0 and P1, NMOS transistors N4 and N5 pre-charge nodes V_{A} and V_{B}. Furthermore, PMOS transistors P2 and P3, and NMOS transistors N0 and N1 form an inverter latch. When the latch circuit is in a latch mode, two input signals INN and INP are latched to the logic high and the logic low states, respectively.

When a clock signal CLK is logic low, NMOS transistors N4 and N5 are in a turned-off state while PMOS transistors P0 and P1 and input terminal switches P5 and P6 maintain a turned-on state. Therefore, nodes V_{A} and V_{B} become high, and the final output signals OUTN and OUTP which pass through inverters INV1 and INV2 remain “low”. In this case, an analog input signal is applied to the gate of NMOS transistors N2 and N3.

On the other hand, the moment that the clock signal CLK goes from logic low to logic high, the PMOS transistors P0 and P1 and the input terminal switches P5 and P6 turn off, and the NMOS transistors N4 and N5 turn on. Thus, electrical charges of the nodes V_{A} and V_{B} are each discharged through NMOS transistors N0 and N2, and N1 and N3, each pair of which is connected in series. In this case, a difference in the amount of current flowing in the NMOS transistors N2 and N3 is caused by the full differential input signals, i.e., signals of nodes. N_{A} and N_{B}. Eventually, a voltage difference occurs between nodes V_{A} and V_{B}, and full differential output signals OUTN and OUTP are latched to the logic high and the logic low states, respectively, by an inverter latch consisting of PMOS transistors P2 and P3, and NMOS transistors N0 and N1.

Based on the foregoing, the latch circuit of FIG. 1 removes static current consumption in a track mode. However, discharging is delayed in the latch circuit since NMOS transistors N0 and N2, and N1 and N3 are connected in series, respectively. FIG. 2A depicts an analog input voltage difference between nodes N_{A} and N_{B} created by a clock signal CLK. Referring to FIG. 2A, if the frequency of a clock signal CLK is 200 MHz (one clock cycle is 5 ns), a voltage difference between full differential input signals, i.e., signals of nodes V_{A} and V_{B}, is reduced by a kick-back voltage. This produces a problem in that it may effect the next clock cycle when a latch is operated at high speed.

FIG. 2B shows the voltages of nodes V_{A} and V_{B} created by a clock signal CLK of 200 million samples per second (Msps). Referring to FIG. 2B, NMOS transistors N2 and N3 are operated in a linear region during a latch mode, and NMOS transistors N2 and N0, and N3 and N1 are connected in series, which increases the required time for discharging. Therefore, the latch circuit has a drawback in that it cannot be used in a system requiring high-speed operation.

### SUMMARY OF THE INVENTION

To solve the above problems, it is an object of the present invention to provide a high-speed dynamic latch which removes kick-back voltage occurring in the existing latch and compensates for a drawback caused by low-speed charging/discharging.

Accordingly, to achieve the above object, there is provided a high-speed dynamic latch including: a first output node; a second output node; a precharging unit which precharges the first and second output nodes in response to a clock signal, a signal from the first output node, and a signal from the second output node;

a discharging unit which discharges the first output node in parallel in response to one of a pair of differential input signals and a signal from the second output node, and discharges the second output node in parallel in response to the other of the pair of differential input signals and a signal from the first output node; and a current source which sinks current from the discharging unit in response to the clock signal.

### BRIEF DESCRIPTION OF THE DRAWINGS

The above object and advantages of the present invention will become more apparent by describing in detail preferred embodiments thereof with reference to the attached drawings in which:

FIG. 1 shows a conventional dynamic latch circuit;

FIGS. 2A and 2B are graphs showing the simulation results of the circuit of FIG. 1;

FIG. 3 shows a dynamic latch circuit according to the present invention;

FIG. 4 is a graph showing the simulation results of FIG. 3; and

FIG. 5 is a graph showing the simulation results with respect to the discharge time of FIG. 3.

### DETAILED DESCRIPTION OF THE INVENTION

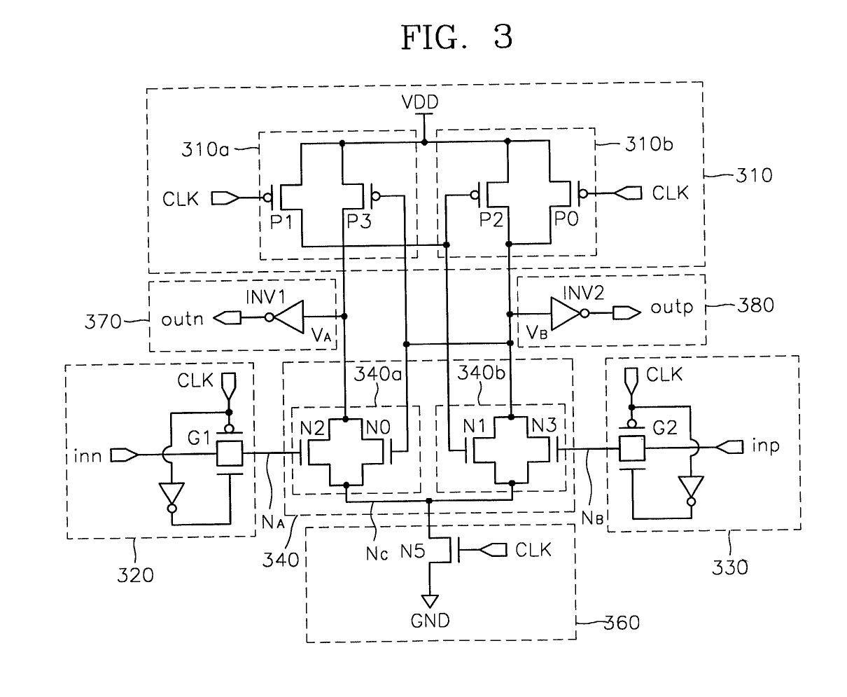

Referring to FIG. 3, which shows a dynamic latch circuit according to the present invention, the dynamic latch circuit includes a precharging unit 310, a discharging unit 340, a current source 360, first and second input units 320 and 330, and first and second output units 370 and 380. The precharging unit 310 precharges a first output node V_{A} and a second output node V_{B} in response to a clock signal CLK, a signal from the first output node V_{A}, and a signal from the second output node V_{B}. The discharging unit 340 discharges the first output node V_{A} in parallel in response to one of a pair of differential input signals, i.e., a signal of node N_{A}, and a signal from the second output node V_{B}, and discharges the second output node V_{B} in parallel in response to the other differential input signal, i.e., a signal of node N_{B}, and a signal from the first output node V_{A}.

The current source 360 sinks current from the discharging unit 340 in response to a clock signal CLK. The first input unit 320 transmits a first input signal INN to a node N_{A} in response to the clock signal CLK. The second input unit 330 transmits a second input signal INP to a node N_{B} in response to a clock signal CLK.

The first and second input signals INN and INP are differential input signals, and thus signals of the node N_{A} and the node N_{B} are the differential input signals. The first output unit 370 inverts a signal from the first output node V_{A} to output the result as a first output signal OUTN. The second output unit 380 inverts a signal from the second output node V_{B} to output the result as a second output signal OUTP.

More specifically, the precharging unit 310 is divided into first and second precharging units 310a and 310b. The first precharging unit 310a includes a PMOS transistor P1 having a source connected to a first reference voltage node, i.e. power voltage node V_{DD}, a gate connected to a clock signal CLK, and a drain connected to the first output node V_{A}; and a PMOS transistor P3 having a source connected to the first reference voltage node V_{DD}, a gate connected to the second output node V_{B}, and a drain connected to the first output node V_{A}. The second precharging unit 310b includes a PMOS transistor P0 having a source connected to the first reference voltage node V_{DD}, a gate connected to a clock signal CLK, and a drain connected to the second output node V_{B}; and a PMOS transistor P2 having a source connected to the first reference voltage node V_{DD}, a gate connected to the first output node V_{A}, and a drain connected to the second output node V_{B}.

The discharging unit 340 is divided into first and second discharging units 340a and 340b. The first discharging unit 340a includes an NMOS transistor N2 having a drain connected to the first output node V_{A}, a gate connected to the other of the differential input signals, i.e., a signal at a node N_{A}, and a source connected to a node N_{C}; and an NMOS transistor N0 having a drain connected to the first output node V_{A}, a gate connected to the second output node V_{B}, and a source connected to a node N_{C}. The second discharging unit 340b includes an NMOS transistor N3 having a drain connected to the second output node V_{B}, a gate connected to the other of differential input signals, i.e., a signal at a node N_{B}, and a source connected to the node N_{C}; and an NMOS transistor N1 having a drain connected to the second output node V_{B}, a gate connected to the first output node V_{A}, and a source connected to the node N_{C}. The current source 360 is connected between a node N_{C} and a second reference voltage node, i.e., ground voltage node GND, and includes an NMOS transistor N5 to the gate of which a clock signal CLK is applied.

The detailed circuit operation will now be described with reference to FIG. 3. Firstly, during a track mode in which a clock signal CLK is at logic low, the NMOS transistor N5 is in a turned-off state, and the PMOS transistors P1 and P0 of the precharging unit 310, and transmission gates G1 and G2 of the first and second input units 320 and 330 maintain a turned-on state. Thus, the first and second output nodes V_{A} and V_{B} become “high”, and the final output signals OUTN and OUTP passing through the inverters INV1 and INV2 of first and second output units 370 and 380 maintain a logic “low” level. In this case, analog differential input signals INN and INP are applied to the transmission gates G1 and G2 of the first and second input units 320 and 330.

During a latch mode in which a clock signal CLK goes from logic low to logic high, the PMOS transistors P1 and P0, and the transmission gates G1 and G2 of the first and second input units 320 and 330 turn off, while the NMOS transistor N5 turns on. Thus, electrical charges of the first and second output nodes V_{A} and V_{B} begin to be discharged within the first and second discharging units 340a and 340b through the NMOS transistors N0 and N2, and N1 and N3, each pair of which is connected in parallel. In this case, a difference in the amount of current flowing in the NMOS transistors N2 and N3 is caused by the full differential input signals, i.e., signals of nodes N_{A} and N_{B}. Therefore, a voltage difference occurs between the first and second output nodes. This causes an inverter latch comprised of the PMOS transistors P2 and P3, and NMOS transistors N0 and N1 to latch full differential output signals OUTN and OUTP passing through the inverters INV1 and INV2 to a logic high and a logic low state, respectively.

Furthermore, the NMOS transistor N5 for controlling precharge and discharge of the output nodes V_{A} and V_{B} is commonly connected to the sources of NMOS transistors N0, N1, N2, and N3 within the discharging unit 340, which prevents a restriction in a high-speed operation caused by kick-back voltage.

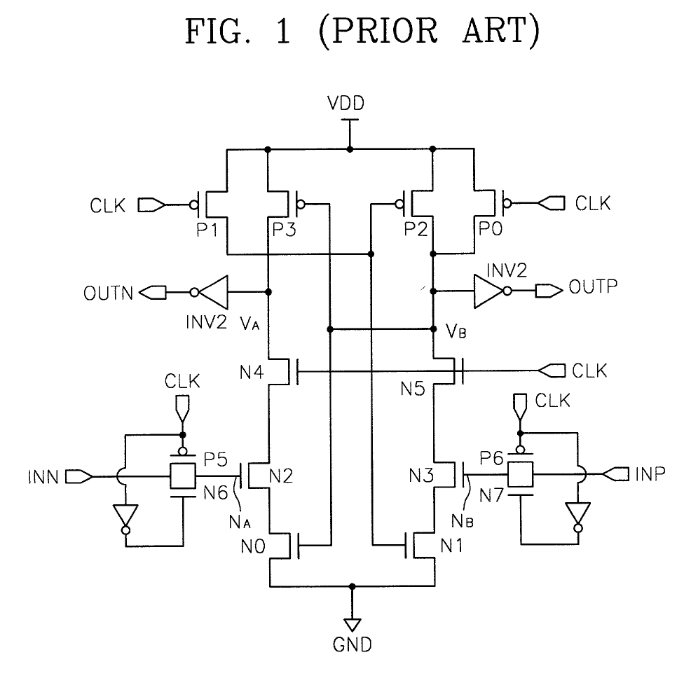

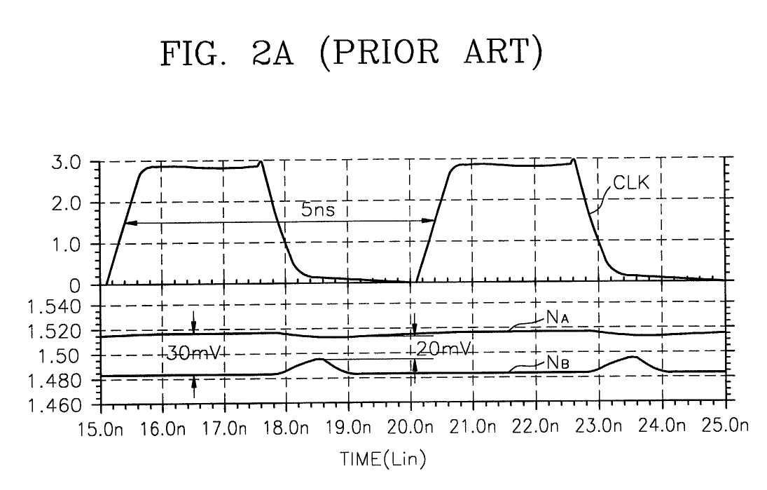

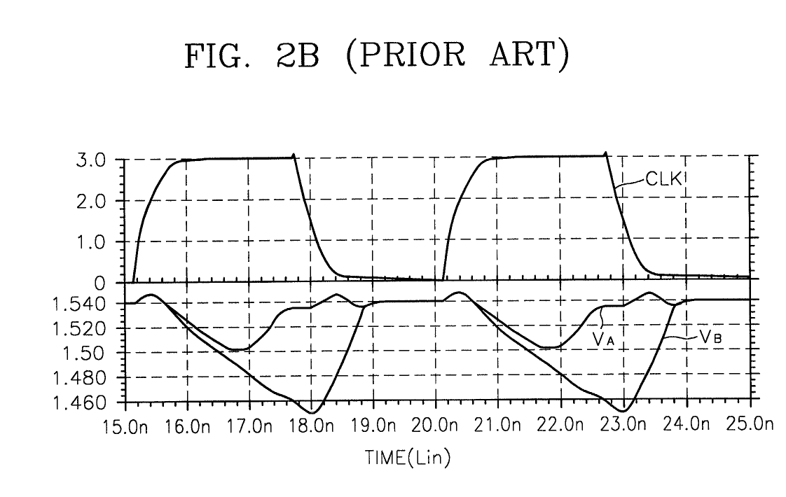

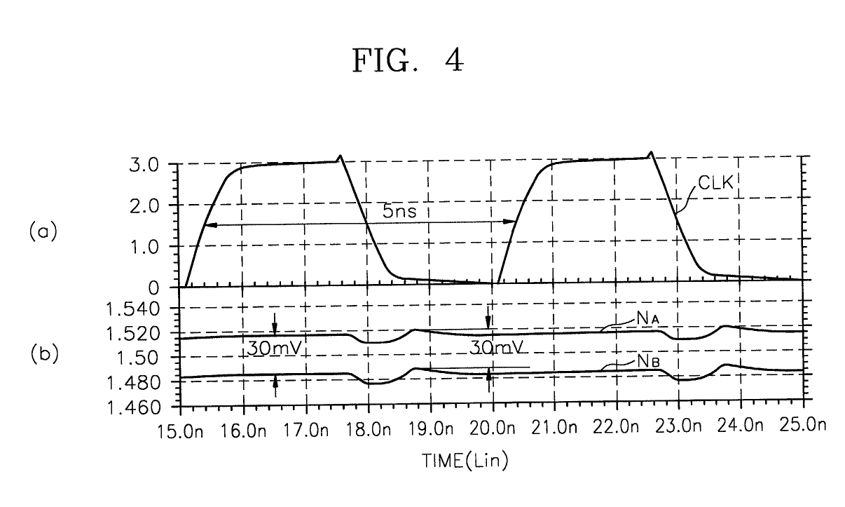

FIG. 4 is a graph showing the simulation result with respect to kick-back voltage of the dynamic latch circuit of FIG. 3. FIG. 4(a) indicates a clock signal CLK of 200 million samples per second (Msps), and FIG. 4(b)) shows a voltage difference between full differential input signals, i.e., signals of the node NA and the node NB. As shown in FIG. 4, a clock signal CLK affects analog input signals IN and INP by kick-back voltage. However, contrary to the existing latch shown in FIG. 1, a voltage difference between full differential input signals, i.e., signals of the node N_{A} and the node N_{B}, is not reduced. Therefore, during high-speed operation, a voltage difference between analog input signals remains constant in each clock cycle.

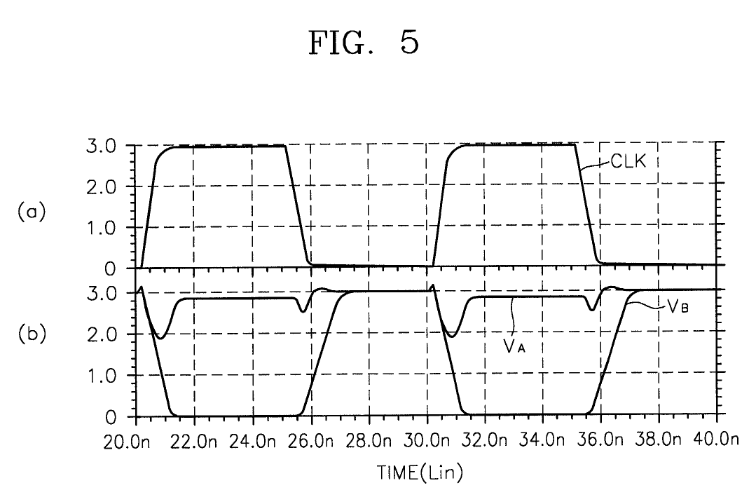

Furthermore, the discharge time of output nodes V_{A} and V_{B} significantly affects high-speed operation. Generally, the falling and rising time of the two nodes are forced to be one half of the pulse width of operation frequency. In the dynamic latch circuit of FIG. 3, the NMOS transistors N0 and N1 are connected in parallel to N2 and N3, respectively, instead of being connected in series like in the conventional dynamic latch circuit, which quickens the discharge time of output nodes V_{A} and V_{B}. FIGS. 5A and 5B are graphs showing the simulation results to the discharge time of nodes V_{A} and V_{B} in the circuit of FIG. 3. FIG. 5(a) indicates a clock signal CLK of 200 MHz, and FIG. 5(b) is a voltage waveform of output nodes V_{A} and V_{B}. As shown in FIG. 5, the discharge time of output nodes V_{A} and V_{B} is about 1 ns, so operation speed higher than 500 MHz can be obtained. In this case, the simulation of FIG. 5 uses a 0.6 μm CMOS process model parameter.

As described above, the latch circuit according to the present invention is capable of removing kick-back voltage which may occur in the existing latch and compensating for a disadvantage resulting from low-speed charge/discharge, which improves its operation speed. Thus, the latch circuit according to the present invention can be used in a high-speed analog/digital converter of operation speed higher than 500 MHz.

What is claimed is:

1. A high-speed dynamic latch comprising:
a first output node;
a second output node;
a precharging unit which precharges the first and second output nodes in response to a clock signal, a signal from the first output node, and a signal from the second output node;
a discharging unit which discharges the first output node in parallel in response to one of a pair of differential input signals and a signal from the second output node, and discharges the second output node in parallel in response to the other of the pair of differential input signals and a signal from the first output node; and
a current source which sinks current from the discharging unit in response to the clock signal.

2. The high-speed dynamic latch of claim 1, further comprising:
a first input unit which receives one of the pair of differential input signals in response to the clock signal; and
a second input unit which receives the other of the pair of differential input signals in response to the clock signal.

3. The high-speed dynamic latch of claim 1, further comprising:
a first output unit which inverts the signal from the first output node to output the inverted result; and
a second output unit which inverts the signal from the second output node to output the inverted result.

4. The high-speed dynamic latch of claim 1, wherein the precharging unit comprises:
a first precharging unit which precharges the first output node in response to the clock signal and the signal from the second output node; and
a second precharging unit which precharges the second output node in response to the clock signal and the signal from the first output node.

5. The high-speed dynamic latch of claim 1, wherein the discharging unit comprises:
a first discharging unit which discharges the first output node in parallel, in response to one of the pair of differential input signals and the signal from the second output node; and
a second discharging unit which discharges the second output node in parallel, in response to the other of the pair of differential input signals and the signal from the first output node.

6. The high-speed dynamic latch of claim 4, wherein the first precharging unit comprises:
a first MOS transistor having a source connected to a first reference voltage node, a gate connected to the clock signal, and a drain connected to the first output node; and
a second MOS transistor having a source connected to the first reference voltage node, a gate connected to the second output node, and a drain connected to the first output node.

7. The high-speed dynamic latch of claim 4, wherein the second precharging unit comprises:
a first MOS transistor having a source connected to a first reference voltage node, a gate connected to the clock signal, and a drain connected to the second output node; and
a second MOS transistor having a source connected to the first reference voltage node, a gate connected to the first output node, and a drain connected to the second output node.

8. The high-speed dynamic latch of claim 5, wherein the first discharging unit comprises:
a first MOS transistor having a drain connected to the first output node, a gate connected to one of the pair of differential input signals, and a source connected to a common node; and
a second MOS transistor having a drain connected to the first output node, a gate connected to the second output node, and a source connected to the common node.

9. The high-speed dynamic latch of claim 5, wherein the second discharging unit comprises:
a first MOS transistor having a drain connected to the second output node, a gate connected to the other of the pair of differential input signals, and a source connected to a common node; and
a second MOS transistor having a drain connected to the second output node, a gate connected to the first output node, and a source connected to the common node.

10. The high-speed dynamic latch of claim 1, wherein the current source is connected between the discharging unit and a second reference voltage node, and comprises a MOS transistor to the gate of which the clock signal is applied.
